(19) United States
(12) Patent Application Publication
(10) Pub. No.: US 2013/0070797 A1
(43) Pub. Date: Mar. 21, 2013

(54) LASER UNIT WITH SUPPRESSED FEEDBACK

(71) Applicants: Andreas WITTMANN, Giswil (CH); Michel STUDER, Luzern (CH); Rui PROTASIO, Luzern (CH); Corrado FRASCHINA, Ebikon (CH)

(72) Inventors: Andreas WITTMANN, Giswil (CH); Michel STUDER, Luzern (CH); Rui PROTASIO, Luzern (CH); Corrado FRASCHINA, Ebikon (CH)

(73) Assignee: LEISTER PROCESS TECHNOLOGIES, Kagiswil (CH)

(21) Appl. No.: 13/252,294

(22) Filed: Oct. 4, 2011

(30) Foreign Application Priority Data
Sep. 15, 2011 (EP) 11 401 593.6

(51) Int. Cl. H01S 5/183

(52) U.S. Cl. 372/43.01

(57) ABSTRACT

Laser unit, preferably for gas detection, with a semiconductor laser chip comprising an output mirror with an exit zone for a laser beam and an optical element that reduces self-mixing which is arranged at the exit zone, wherein optical element and laser chip are connected with each other with direct physical contact over an entire surface, at least in the exit zone. Said optical element is connected to the laser chip positively or by means of an optical medium. Thereby optionally a beam-shaping element may be arranged on the optical element that is connected positively or by means of an optical medium with the optical element. Preferably beam-shaping element and optical element have similar or identical refractory indices and are connected with each other and with the laser chip by adhesive agents having corresponding refractory indices.

### CROSS-REFERENCE TO RELATED APPLICATION

The present application claims priority under 35 USC §119 to European Patent Application No. 11 401 593.6 filed Sep. 15, 2011, the entire disclosure of which is incorporated herein by reference.

### TECHNICAL FIELD OF THE INVENTION

The invention relates to a laser unit with a semiconductor laser chip that comprises an output mirror with an exit zone for a laser beam that is primarily intended for gas detection but can also be used in other areas of application, for example in telecommunications, and is capable of reducing and/or suppressing the back reflection of the laser light into the exit zone of the laser.

### DESCRIPTION OF THE RELATED ART

For a multitude of tasks in the sectors of security, convenience, and environmental protection, there is a great demand for cost-efficient, reliable, and highly sensitive gas detectors. Known gas sensors frequently detect gases by means of absorption spectroscopy. For example, with this technology, a laser beam of suitable frequency is passed through a gas or mixture of gases that absorbs the laser light, at least partially. The frequency depends on the gas to be detected and is selected to ensure the strongest possible interaction of the laser light with the gas atoms and/or gas molecules. Here, the degree of absorption of the laser beam is used as indicator for the gas concentration of the gas in question. Lasers with spectrally single-mode beams are especially suitable for gas detection.

In laser absorption spectroscopy, the laser beam emitted by the laser diode is detected by a light or heat sensitive detector element after passing through a gas or gas mixture, and the received signal is fed into a signal analyzer for evaluation. The signal analyzer separates constant interference patterns from the received signal. However, it is not able to completely eliminate from the received signal the constantly changing interference patterns that will occur more or less at all times, which, due to the increased noise, has the effect of distinctly degrading the detection sensitivity for the gas to be detected.

On the one hand, changing interference patterns are caused by thermal influences affecting the semiconductor laser unit by changing the length of the optical path of the laser light to the detector element. In addition, such interference patterns can be generated by reflections of the laser light on interior surfaces of the housing of the semiconductor laser unit, or on boundary surfaces of beam-shaping or beam-guiding optical elements arranged inside the housing, such as lenses or mirrors, or also on the interior or exterior surface of the exit window for the laser beam. As a rule, these interference patterns also depend on temperature in that the optical path length for the laser beam inside the housing changes with the temperature. Especially back reflections of the laser light into the laser aperture of the semiconductor laser chip have an extremely negative effect in terms of noise on the laser beam emitted by the semiconductor laser chip.

It is common practice to arrange the semiconductor laser chip of a semiconductor laser unit on a Peltier element that is arranged between the housing and the semiconductor laser chip and serves as an active heat sink, in order to limit the thermal influences and thereby the occurrence of interference patterns. It is also known from prior art to connect an optical element that influences the laser beam with the semiconductor laser chip in a thermally conductive connection so that the optical element has a defined thermal state in relation to the semiconductor laser chip. The defined thermal state in relation to the temperature-controlled semiconductor laser chip produces a stable optical path length of the laser beam between the semiconductor laser chip and the beam-shaping element.

This type of thermal coupling is known from EP 2 320 215 A1, for example. This patent disclosure discloses a semiconductor laser arrangement, specifically for gas detection, with a housing with electrical connections that has a bottom and preferably an exit window. A semiconductor laser chip and a temperature control device for the semiconductor laser chip are arranged in the housing. The temperature control device is formed by a Peltier element that is connected with the bottom of the housing with its lower flat surface and with the semiconductor laser chip with its upper flat surface. A temperature-controlled beam-shaping element, for example a collimating microlens, is arranged between the semiconductor laser chip and the exit window of the housing. The beam-shaping element is in close physical contact with the semiconductor laser chip, with one of its boundary surfaces preferably materially or adhesively connected with the laser aperture. Thereby, the beam-shaping element also has a defined thermal state relative to the semiconductor laser chip.

However, the known semiconductor laser arrangement described above wherein the beam-shaping element is in direct physical contact with the laser aperture allows unimpeded interfering back reflections of the laser light to occur without influencing them.

In order to reduce back reflections, optical insulators can be used; however, they are usually very large in relation to the dimensions of the semiconductor laser and take up a lot of room in a compact optical sensor. In addition, the relatively high price of such a system that usually consists of several optical elements prohibits such a system from being installed in a cost-efficient detection system.

As an alternative to optical insulators, an optical element can be used that merely rotates the polarization direction of the back-reflected light. Sample references are the publications WO 01/02838 A1 and EP 0 729 565 B1. However, even if it has an antireflective coating, the installation of such an optical element as a discrete element does not offer any real advantages due to the additional optical boundary surfaces. The back-reflections occurring at these boundary surfaces even in the presence of high-quality antireflective coatings produce optical interference in the beam path. This greatly reduces the advantage of the polarization rotation and may even lead to more optical noise. This fact, and the additional cost of an antireflective coating were the reasons why such solutions for the gas absorption were not considered in the past.

### SUMMARY OF THE INVENTION

With reference to the prior art described above, the invention addresses the problem of proposing a solution for further reducing to a significant degree the interference phenomena of the laser beam.

According to the invention, this problem is solved by a laser unit for gas detection with the characteristics as described and claimed.

The invention is based on preventing a strong interaction of the laser light reflected back from outside via the exit zone into the optical resonator of the semiconductor laser chip with the laser light to be emitted. For this purpose, the polarization direction of the back-reflected laser light is influenced. The goal is to change, i.e. to rotate, the plane of polarization in such a way that it extends at the largest possible angle, ideally orthogonally, to the plane of polarization of the emitted laser beam. It is an aspect of the invention to install an optical element with the characteristics described above in such a way that additional boundary surfaces in the beam path are avoided. As a consequence, the modulation of the emitted laser beams due to back-reflections is significantly reduced.

In the following, the invention is explained in detail with reference to three embodiments shown in the drawing. Additional characteristics of the invention are given in the following description of the embodiment of the invention in conjunction with the claims and the attached drawing. The individual characteristics of the invention may be realized either individually by themselves or in combinations of several in different embodiments of the invention.

### BRIEF DESCRIPTION OF THE DRAWINGS

FIG. 1 shows a laser unit according to the invention with an optical element that reduces self-mixing that is connected with the semiconductor laser chip positively or by means of an optical medium;

FIG. 2 shows the laser unit in FIG. 1 with a beam-shaping element that is connected positively or by means of an optical medium; and

FIG. 3 shows a wafer-bonded semiconductor laser chip with an optical element that reduces self-mixing.

### DETAILED DESCRIPTION OF THE INVENTION

In the laser unit according to the invention, in the exit zone of the output mirror of the semiconductor laser chip, an optical element is arranged that reduces the sensitivity of the laser unit for self-mixing effects. The optical element that reduces self-mixing is largely permeable for laser light and overlaps the output mirror at least in the area of the exit zone. The optical element that reduces self-mixing and the output mirror are connected with each other over their full surfaces at least at the exit zone. The output mirror may have a metal coating and/or other coatings that have an opening for the light emission in the area of the exit zone.

In a preferred embodiment of the invention, the optical element that reduces self-mixing is in material contact with the semiconductor laser chip, or is connected with it via an optical medium. The optical element that reduces self-mixing is therefore also in direct contact with the semiconductor laser chip so that a thermal coupling is established that permits a temperature equalization.

This optical element may generally consist of an optical insulator. However, it is also sufficient if the element that reduces self-mixing influences only the polarization direction. In this case, it comprises optically active material that is structured in such a way that it rotates the plane of oscillation of a passing light beam (laser beam). The extent of the rotation of the plane of oscillation depends on the wavelength of the incident light and also on the alignment of the optical element that reduces self-mixing in relation to the light beam. Some crystals rotate light, as a consequence of the asymmetry of the crystal structure. But it is also possible to use transparent materials that themselves are not optically active, for example by applying a magnetic field in view of the Faraday effect, or an electrical field, for example to a liquid crystal cell, thereby rotating the polarization direction of the light beam.

Preferably, such an optical element that reduces self-mixing takes the form of a small smooth and flat plate that has specific axes that are dependent on the structure of the material, with the polarization of the electromagnetic radiation of the laser beam to be arranged at a certain angle to said axes in order to achieve an optimal effect.

The optical element that reduces self-mixing that is traversed by the laser beam emitted by the laser aperture and, in the opposite direction, by the back-reflections of the laser beam significantly changes the polarization direction of the back-reflected laser beam in relation to the emitted laser beam, thereby reducing the modulation of the laser light generated by the semiconductor laser chip. With congruent planes of polarization of the laser beams travelling in opposite directions, the modulation is the largest, and with orthogonally aligned planes of polarization the smallest. Preferably, in the laser unit according to the invention, a small delay plate, for example a small quartz glass plate, is used as the optical element that reduces self-mixing. Such a quartz glass plate has an optical activity that is determined by the crystallization of the quartz in an enantimorphous structure. Preferably, the optical axis is arranged so that it is located in the sectional plane of the crystal.

Such delay plates, also called A/n plates or wave plates, are optical elements that are capable of changing the polarization and the phase of passing electromagnetic waves such as laser light. As a rule, n is a natural number. A λ/4 plate, for example, delays light that is polarized parallel to a component-specific axis by a one quarter wavelength in relation to light that is polarized perpendicular to this. With suitable radiation, it is able to generate circularly or elliptically polarized light from linearly polarized light, or re-convert circularly polarized light to linearly polarized light. The polarization changes are achieved by the circumstance that the laser light passing through is divided into two perpendicular polarization directions that pass through the λ/4 plates at different speeds, with their phases shifted relative to each other. Typically, such a plate consists of a doubly reflecting crystal of suitable thickness and alignment, or a foil manufactured accordingly.

For example, such a λ/4 plate of the laser unit according to the invention generates a 90° rotation of the polarization of the laser radiation between the emitted and the back-reflected beams so that the two laser beams proceeding in different directions do not interfere within the semiconductor laser chip. This avoids, or greatly reduces, self-mixing effects in the semiconductor laser chip. For this purpose, in relation to the semiconductor laser chip, the λ/4 plate is preferably arranged in such a way that the optical axis of the λ/4 plate assumes an angle of 45° to the polarization direction of the linearly polarized laser beam of the semiconductor laser chip. Instead of the λ/4 plate, it is also possible to use a delay plate whose thickness is an odd multiple of a quarter wavelength of the laser beam.

In an advantageous embodiment of the laser unit according to the invention, the output mirror of the semiconductor laser chip is mounted on the optical element that reduces self-mixing. Preferably, a thin quartz glass plate is used here as an optical element that reduces self-mixing. The mirror coatings are preferably applied by means of vapor deposit or sputtering (for example silicon oxide (SiOx) and titanium oxide (TiO2)), or chemically by means of PECVD, i.e. by plasma-enhanced chemical vapor deposit, with those layers containing amorphous silicon or silicon oxide, for example. The unit consisting of the optical element that reduces self-mixing and the output mirror that is produced separately from the VCSEL semilaser structure is preferably joined with the semilaser structure by means of a known wafer-bonding process, with the output mirror pointing in the direction of the semilaser structure. For example, a wafer-bonding process that is suitable for producing a conventional VCSEL semiconductor laser chip, i.e. one without an optical element that reduces self-mixing, is disclosed in the patent EP 1 378 039B1.

In the known process, an upper and a lower substrate layer are joined positively with a central wave conductor layer by means of wafer-bonding. The three layers are themselves multilayered. The upper and the lower substrate layer each comprise a gallium arsenite substrate (GaAs substrate) and a mirror layer that consists of several semiconductor layers produced epitaxially. The wave conductor layer is structured conventionally. After the two substrate layers have been joined positively with the wave conductor layer, the outward-facing GaAs substrate is removed on the upper substrate layer, i.e. on the flat surface of the semiconductor laser chip that is intended for outputting the laser beam, so that the remaining mirror layer may act as output mirror for the laser beam. The lower substrate layer remains unchanged, with the mirror that is embedded in the semiconductor laser chip and faces the output mirror forming the rear laser mirror.

The wafer-bonded semiconductor laser chip with the element that reduces self-mixing that is used for the laser unit according to the invention in a preferred embodiment is produced in a similar way. However, instead of the upper substrate layer, the unit, made of one piece, is used as optical element that reduces self-mixing with a dielectrically produced output mirror. Because the optical element that reduces self-mixing is permeable for laser light, the output mirror is able to function without any additional measures. The laser beam exiting from the output mirror passes through the optical element that reduces self-mixing without any problems.

In one embodiment of the laser unit according to the invention with a semiconductor laser chip and a optical element that reduces self-mixing produced separately, the optical element that reduces self-mixing is preferably connected on the output mirror with an optical medium that has a refractory index that is similar or equivalent to that of the optical element that reduces self-mixing. The optical medium forms a thin and homogeneous layer between the semiconductor laser chip and the optical element that reduces self-mixing. The optical medium consists of a material that absorbs laser light only to a small extent. The optical medium may consist of a layer of adhesive, a layer of gel, or a layer of liquid, for example. In addition, the optical element that reduces self-mixing can be arranged at a slight tilt relative to the output mirror in order to prevent Fabry Perot cavities that may lead to interference.

When the emitted laser beam transits from the output mirror to the optical medium, the light waves of the laser beam are refracted in accordance with the law of refraction. By using an optical medium whose refractory index ideally is identical with the refractory index of the delay plate, a possible reflecting surface for the laser light on the optical element that reduces self-mixing is eliminated. The laser beam passes through the optical medium without the laser light waves changing their direction again when transiting to the optical element that reduces self-mixing.

In one embodiment, the optical element that reduces self-mixing may be joined directly to the semiconductor laser chip during its manufacture, i.e. be integrated in the chip. Preferably, the joint is produced by means of wafer-bonding. Wafer-bonding is a process known from semiconductor and micro systems technology where, for example, two silicon, quartz, or similar wafers are joined without additional means of adhesion. In a preferred embodiment of the laser unit according to the invention, the optical element that reduces self-mixing is attached to a VCSEL laser structure.

In another preferred embodiment of the laser unit according to the invention, the optical element that reduces self-mixing carries an optical beam-shaping element at the exit zone for the laser beam, with the beam-shaping element being indirectly connected with the semiconductor laser chip. Preferably, the beam-shaping element is connected with the optical element that reduces self-mixing either positively or by means of an optical medium. An element of any type may be used. A collimating microlens is preferred, preferably a spherical or semispherical lens, arranged on the optical element that reduces self-mixing.

Preferably, the beam-shaping element is attached to the optical element that reduces self-mixing by means of an optical medium that has a refractory index that is similar or equivalent to that of the beam-shaping element or optical element that reduces self-mixing. The optical medium forms a thin homogeneous layer that is flat on one side and curved on the other, thereby being adapted to the shape of the beam-shaping element.

The optical medium that connects the optical element that reduces self-mixing with the beam-shaping element and/or the semiconductor laser chip may comprise an adhesive, a gel or a liquid, for example. When the laser beam transits from the optical element that reduces self-mixing to the beam-shaping element, the laser beam is refracted at the boundary layers of the adhesive layer only one single time, due to the adapted refractory index of the optical medium.

In one embodiment of the laser unit according to the invention, the optical element that reduces self-mixing is attached to the output mirror by means of a first optical medium, and the beam-shaping element is attached to the optical element that reduces self-mixing by means of a second optical medium, both of which have a refractory index that is identical with the refractory index of the beam-shaping element and of the optical element that reduces self-mixing. Due to the uniform refractory index of the optical medium, of the optical element that reduces self-mixing, and of the beam-shaping element, the composite system consisting of the semiconductor laser chip, the first adhesive layer, the optical element that reduces self-mixing, the second adhesive layer and the beam-shaping element, is reduced to a single refracting boundary surface between these items. The effective boundary surface is located between the output mirror and the first optical medium. This eliminates possible reflective surfaces for the laser light on the optical element that reduces self-mixing and the beam-shaping element.

The advantages that are achieved for the emitted laser beam by the optical medium—adapted to the respective refractory index—between the laser aperture and the optical element that reduces self-mixing, and/or between the optical element that reduces self-mixing and the beam-shaping element, also apply to the back-reflections of the emitted laser beam.

The optical medium may also consist of a thin layer of oil, with the refractory indices of the oil and the optical element that reduces self-mixing matching each other.

Preferably, the thickness of the optical medium should be kept very thin. It should be less than 100 μm so that Fabry Perot cavities that may possibly form lead to relatively small low-frequency etalons that do not interfere with the signal of a gas detection device using the laser unit according to the invention as sending unit because they are only detected as background noise.

Also, a relatively thin layer of the optical element that reduces self-mixing, for example a thickness of less than 200 μm, and/or its relatively small mass, favor a very good thermal adaptation of the beam-shaping element to the temperature of the laser chip.

An embodiment of the invention is preferred where the semiconductor laser chip is enclosed in a housing with an exit opening for the laser beam, preferably a hermetically sealed housing with an exit window.

By means of the laser unit according to the invention, it is possible to distinctly reduce interference phenomena of the laser beam generated by the semiconductor laser chip. Due to the optical element that reduces self-mixing that spatially rotates the polarization direction of back-reflections of the laser beam, the interaction of the laser light reflected back into the laser aperture with the laser light to be emitted is minimized. In addition, due to the attachment of the optical element that reduces self-mixing to the laser aperture and, optionally, the attachment of the beam-shaping element to the optical element that reduces self-mixing by means of an optical medium with the same refractory index, the number of the reflecting surfaces facing the laser aperture in the beam path of the laser beam is reduced to a minimum. Furthermore, this couples the optical element that reduces self-mixing and the beam-shaping element thermally with the semiconductor laser chip in order to reduce the thermal influences on the optical path length in the housing of the laser unit. As laser source, surface-emitting sources (VCSEL) as well as edge emitters can be used. Since the dereflection of the optical element that reduces self-mixing can be eliminated, only a small sum needs to be invested for a quartz-based delay plate, which makes it possible to produce a very cost-efficient laser module of small dimensions.

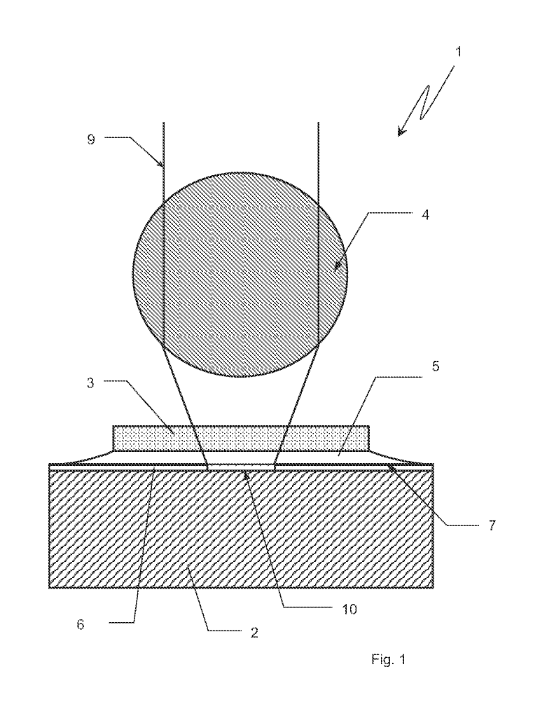

FIG. 1 shows a laser unit 1, preferably for use in gas detection, with a hermetically sealed housing (not shown in the drawing) with an exit window for the laser beam in which a semiconductor laser chip 2 is arranged. In the area of an exit zone 10 for a laser beam 9, the semiconductor laser chip 2 carries a λ/4 plate 3 that is connected with an output mirror 6 of the semiconductor laser chip 2 by means of an adhesive layer 5 as an optical medium made of adhesive. The λ/4 plate 3 is flat, the same as the adhesive layer 5 with which the λ/4 plate 3 is attached to the flat surface 7 of the semiconductor laser chip 2 including the exit zone 10. The adhesive layer 5 extends over the entire exit zone 10. The adhesive layer 5 that connects the output mirror 6 and the optical element that reduces self-mixing 3 has a refractory index that is identical to that of the optical element that reduces self-mixing 3. At a distance from the λ/4 plate 3, an optional microlens 4 is arranged that is attached to a holder (not shown) that extends from the housing of the laser unit.

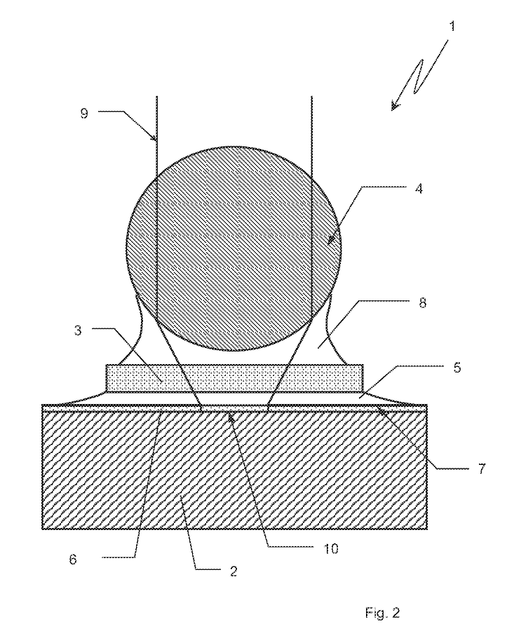

FIG. 2 shows a variant of the embodiment shown in FIG. 1, with a microlens 4 in the form of a spherical lens arranged on the optical element that reduces self-mixing 3. A second adhesive layer 8 that connects the microlens 4 and the λ/4 plate 3 extends between the λ/4 plate 3 and the microlens 4. The second adhesive layer 8 is flat on the side associated with the λ/4 plate 3 and concave on the side facing the microlens 4. The shape of the meniscus of the second adhesive layer 8 corresponds to the radius of the microlens 4. The first adhesive layer 5, arranged between the semiconductor laser chip 2 and the optical element that reduces self-mixing, and the second adhesive layer 8—preferably both thinner than the λ/4 plate 3—have a refractory index that is largely identical with that of the material of the λ/4 plate 3 and of the microlens 4. A diverging laser beam 9 coming from the output mirror 6 at the exit zone 10 extends into the microlens 4 without change of direction. The microlens 4 collimates the laser beam 9 behind the second adhesive layer 8.

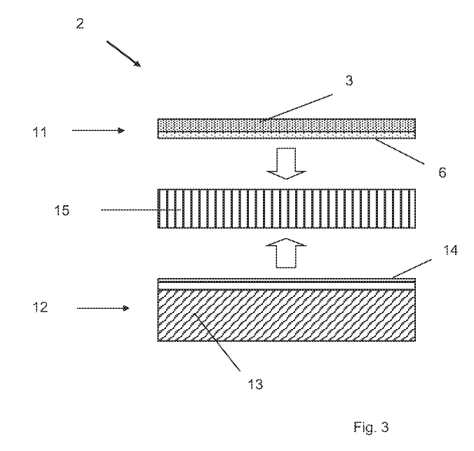

FIG. 3 shows the structure of a wafer-bonded semiconductor laser chip 2 with an optical element that reduces self-mixing 3. The semiconductor laser chip 2 is shown prior to wafer-bonding. By means of wafer-bonding, an upper substrate layer 11 is connected with a wave conductor layer 15 from above, and a lower substrate layer 12 from below. The upper substrate layer 11 comprises the optical element that reduces self-mixing 3 with the output mirror 6. The lower substrate layer 12 comprises a lower GaAs substrate 13 and a rear laser mirror 14 arranged thereon. The figure is not to scale.

Although the invention has been shown and described with respect to certain preferred embodiments, it is obvious that equivalents and modifications will occur to others skilled in the art upon the reading and understanding of the specification. The present invention includes all such equivalents and modifications, and is limited only by the scope of the following claims.

1. A laser unit with a semiconductor laser chip that comprises an output mirror with an exit zone for a laser beam, wherein an optical element that reduces self-mixing is arranged at the exit zone, with the optical element that reduces self-mixing and the laser chip being connected with each other over the entire surface, at least in the exit zone,
wherein the self-mixing reducing optical element is a delay plate and has a thickness that generates a delay corresponding to an even or odd multiple of a one quarter wavelength of the laser beam.

2. The laser unit according to claim 1, wherein the optical element that reduces self-mixing is connected positively or by means of an optical medium with the laser chip.

3. (canceled)

4. The laser unit according to claim 1, wherein the optical element that reduces self-mixing is a quartz plate.

5. The laser unit according to claim 1, wherein the output mirror is mounted on the optical element that reduces self-mixing and is attached by means of wafer-bonding as one unit to the laser chip consisting of a VCSEL semilaser structure.

6. The laser unit according to claim 1, wherein the optical element that reduces self-mixing is attached to a VCSEL laser structure by means of wafer-bonding.

7. The laser unit according to claim 1, wherein an optical beam-shaping element is arranged on the optical element that reduces self-mixing.

8. The laser unit according to claim 7, wherein the optical element that reduces self-mixing is connected positively or by means of an optical medium with the beam-shaping element.

9. The laser unit according to claim 2, wherein the optical medium between the optical element that reduces self-mixing and the semiconductor laser chip has a refractory index that is similar to or identical with that of the optical element that reduces self-mixing, and/or that the optical medium between the optical element that reduces self-mixing and the beam-shaping element has a refractory index that is similar to or identical with that of the optical element that reduces self-mixing or that of the beam-shaping element.

10. The laser unit according to claim 9, wherein the optical medium is an adhesive, a gel and/or a liquid.

11. The laser unit according to claim 1, wherein the semiconductor laser chip is enclosed in a housing with an exit opening for the laser beam.

12. The laser unit according to claim 1, configured for gas detection.

13. The laser unit according to claim 2, wherein the delay plate is a quartz plate.

14. The laser unit according to claim 7, wherein the optical beam-shaping element is a spherical or semispherical lens in the form of a microlens.

15. The laser unit according to claim 11, wherein the housing is hermetically sealed with an exit window.
